(19) United States
(12) Patent Application Publication
(10) Pub. No.: US 2026/0033090 A1
(43) Pub. Date: Jan. 29, 2026

(54) DISPLAY PANEL AND DISPLAY APPARATUS

(71) Applicant: TIANMA ADVANCED DISPLAY TECHNOLOGY INSTITUTE (XIAMEN) CO., LTD., Xiamen (CN)

(72) Inventors: Yingying WU, Xiamen (CN); Yuqi HU, Xiamen (CN); Wenxin JIANG, Xiamen (CN)

(21) Appl. No.: 19/346,624

(22) Filed: Oct. 1, 2025

(30) Foreign Application Priority Data
Jun. 27, 2025 (CN) 202510874600.9

(51) Int. Cl. H10H 29/49; G09G 3/32; H10H 29/32

(52) U.S. Cl. CPC H10H 29/49; G09G 3/32; H10H 29/32; G09G 2300/0426; G09G 2300/043; G09G 2320/0233

(57) ABSTRACT

A display panel and a display apparatus. The display panel includes a pixel circuit, a first signal line extending along a first direction, and a second signal line extending along a second direction. The first direction intersects with the second direction, and the first direction and the second direction are parallel to a plane of the display panel, respectively. The pixel circuit includes a drive transistor and a storage capacitor. The storage capacitor includes a first plate and a second plate. The first plate is connected to a gate of the drive transistor, and the second plate is electrically connected to the first signal line. The second signal line is electrically connected to the first signal line. The second plate, the first signal line, and the second signal line are disposed in different layers. The display panel of the present disclosure can improve display uniformity.

### CROSS-REFERENCE TO RELATED APPLICATION

The present application claims priority to Chinese Patent Application No. 202510874600.9, filed on Jun. 27, 2025, the content of which is incorporated herein by reference in its entirety.

### TECHNICAL FIELD

The present disclosure relates to the technical field of displaying and, in particular, to a display panel and a display apparatus.

### BACKGROUND

A display panel is provided with pixel circuits to drive light-emitting devices, which require power signals to operate. Multiple capacitor plates in a pixel circuit row are interconnected to form transverse wirings. Signal lines arranged in the longitudinal direction are electrically connected to the transverse wirings in a crossing manner to form a mesh wiring, through which power signals are transmitted. Due to a significant difference in square resistance between the longitudinal signal lines and the transverse wirings, the in-plane uniformity of the power signals is affected, and thus the display uniformity is affected.

### SUMMARY

In an aspect, the present disclosure provides a display panel. The display panel includes a pixel circuit, a first signal line extending along a first direction, and a second signal line extending along a second direction. The first direction intersects with the second direction, and the first direction and the second direction are parallel to a plane of the display panel. The pixel circuit includes a drive transistor and a storage capacitor, the storage capacitor includes a first plate and a second plate, the first plate is connected to a gate of the drive transistor, the second plate is electrically connected to the first signal line, and the second signal line is electrically connected to the first signal line. The second plate, the first signal line, and the second signal line are disposed in different layers from one another.

In another aspect, the present disclosure provides a display apparatus. The display apparatus includes a display panel. The display panel includes a pixel circuit, a first signal line extending along a first direction, and a second signal line extending along a second direction. The first direction intersects with the second direction, and the first direction and the second direction are parallel to a plane of the display panel. The pixel circuit includes a drive transistor and a storage capacitor, the storage capacitor includes a first plate and a second plate, the first plate is connected to a gate of the drive transistor, the second plate is electrically connected to the first signal line, and the second signal line is electrically connected to the first signal line. The second plate, the first signal line, and the second signal line are disposed in different layers from one another.

### BRIEF DESCRIPTION OF DRAWINGS

In order to clearly illustrate the technical solutions of embodiments of the present disclosure or of the related art, a brief description will be given below of the drawings required for describing the embodiments or the related art. It is apparent that the drawings in the following description show only some embodiments of the present disclosure, and those skilled in the art can obtain other drawings based on these drawings.

FIG. 1 is a schematic diagram of a pixel circuit according to an embodiment of the present disclosure;

FIG. 2 is a partial schematic diagram of a display panel according to an embodiment of the present disclosure;

FIG. 3 is a schematic diagram of a layer decomposition of FIG. 2 according to an embodiment of the present disclosure;

FIG. 4 is an enlarged view of a local portion in FIG. 2 according to an embodiment of the present disclosure;

FIG. 5 is a partial schematic diagram of a further display panel according to an embodiment of the present disclosure;

FIG. 6 is a schematic diagram of a layer decomposition of FIG. 5 according to an embodiment of the present disclosure;

FIG. 7 is a partial schematic diagram of a further display panel according to an embodiment of the present disclosure;

FIG. 8 is a partial schematic diagram of a further display panel according to an embodiment of the present disclosure;

FIG. 9 is a partial schematic diagram of a further display panel according to an embodiment of the present disclosure;

FIG. 10 is a schematic diagram of a further display panel according to an embodiment of the present disclosure; and

FIG. 11 is a schematic diagram of a display apparatus according to an embodiment of the present disclosure.

### DESCRIPTION OF EMBODIMENTS

In order to more clearly illustrate objectives, technical solutions, and advantages of the embodiments of the present disclosure, the technical solutions in the embodiments of the present disclosure are clearly and completely described in details with reference to the accompanying drawings. The described embodiments are merely part of the embodiments of the present disclosure rather than all of the embodiments. All other embodiments obtained by those skilled in the art based on the embodiments of the present disclosure shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

An embodiment of the present disclosure provides a display panel, in which a first signal line and a second signal line that cross each other in the transverse and longitudinal directions are arranged. The first line is electrically connected to the second signal line, and a plate of a storage capacitor in a pixel circuit is also electrically connected to the first signal line. Furthermore, the first signal line, the second signal line, and the plate of the storage capacitor are disposed in different layers. The first signal line is electrically connected to the second signal line in a crossing manner to form a mesh wiring, which can improve the in-plane uniformity of power signals. By connecting the plate of the storage capacitor to the mesh wiring at the location of the pixel circuit, the uniformity of the power signals received at the location of each pixel circuit is better, thereby improving the display uniformity.

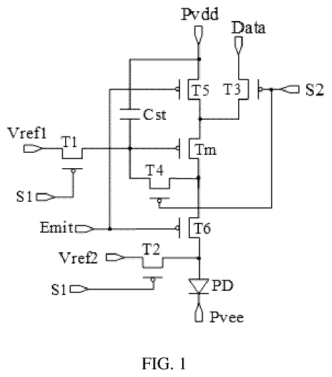

FIG. 1 is a schematic diagram of a pixel circuit according to an embodiment of the present disclosure. As shown in FIG. 1, the pixel circuit includes a drive transistor Tm, a gate reset transistor T1, an electrode reset transistor T2, a data writing transistor T3, a threshold compensation transistor T4, a first light-emitting control transistor T5, a second light-emitting control transistor T6, and a storage capacitor Cst. An operating process of the pixel circuit includes at least a reset stage, a writing stage, and a light-emitting stage. During the reset stage, the gate reset transistor T1 is turned on under the control of a scan signal S1 to write a reset signal Vref1 to a gate of the drive transistor Tm, and the electrode reset transistor T2 is turned on under the control of the scan signal S1 to write a reset signal Vref2 to a first electrode of a light-emitting device PD. During the writing stage, the data writing transistor T3 and the threshold compensation transistor T4 are turned on under the control of a scan signal S2 to write a data voltage Data to the gate of the drive transistor Tm and to perform self-test and compensation on a threshold voltage of the drive transistor Tm. During the light-emitting stage, the first light-emitting control transistor T5 and the second light-emitting control transistor T6 are turned on under the control of a light-emitting control signal Emit. The drive transistor Tm generates a drive current under the control of its gate voltage and provides it to the light-emitting device PD. In the pixel circuit, a first electrode of the first light-emitting control transistor T5 is connected to a first power signal Pvdd, and a second electrode of the light-emitting device PD is connected to a second power signal Pvee. A first plate of the storage capacitor Cst is connected to the gate of the drive transistor Tm, and a second plate is connected to the first power signal Pvdd.

FIG. 1 illustrates a case where a first electrode of the gate reset transistor T1 receives the reset signal Vref1 and a first electrode of the electrode reset transistor T2 receives the reset signal Vref 2. The voltage values of the reset signal Vref1 and the reset signal Vref 2 are different. In some embodiments, the reset signal received by the first electrode of the gate reset transistor T1 and the reset signal received by the first electrode of the electrode reset transistor T2 are the same signal, and the voltage values of the two are the same.

Furthermore, each transistor in the pixel circuit shown in FIG. 1 is a p-type transistor. In some embodiments, the gate reset transistor T1 and the threshold compensation transistor T4 are n-type transistors, and the remaining transistors are p-type transistors.

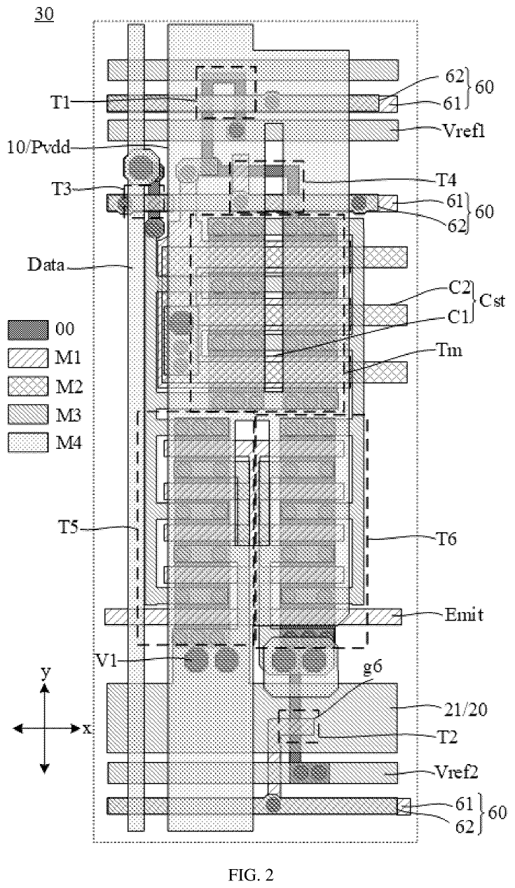

FIG. 2 is a partial schematic diagram of a display panel according to an embodiment of the present disclosure. FIG. 2 illustrates the location of a pixel circuit 30. As shown in FIG. 2, the display panel includes a first signal line 10 extending along a first direction y and a second signal line 20 extending along a second direction x. The first direction y intersects with the second direction x, and the first direction y and the second direction x are parallel to a plane of the display panel, respectively. The connection between the transistors in the pixel circuit in FIG. 2 can be understood in conjunction with FIG. 1.

As shown in FIG. 2, the storage capacitor Cst includes a first plate C1 and a second plate C2. The first plate C1 is connected to the gate of the drive transistor Tm, and the second plate C2 is electrically connected to the first signal line 10. With reference to the structure of the pixel circuit 30 shown in FIG. 1, the second plate C2 is electrically connected to the first signal line 10, and the first signal line 10 provides the first power signal Pvdd required by the pixel circuit 30. The second signal line 20 is electrically connected to the first signal line 10, and the second plate C2, the first signal line 10, and the second signal line 20 are disposed in different layers.

The first signal line 10 and the second signal line 20, whose extension directions intersect with each other, are arranged in the display panel according to the embodiment of the present disclosure. The second signal line 20 is electrically connected to the first signal line 10, the second plate C2 of the storage capacitor Cst is electrically connected to the first signal line 10, and the second plate C2, the first signal line 10, and the second signal line 20 are disposed in different layers. The first signal line 10 is electrically connected to the second signal line 20 in a crossing manner to form a mesh wiring, which can improve the in-plane uniformity of the power signals. By connecting the second plate C2 of the storage capacitor Cst to the mesh wiring at the location of each pixel circuit 30, the uniformity of the power signals received at the location of each pixel circuit 30 is better, thereby improving the display uniformity.

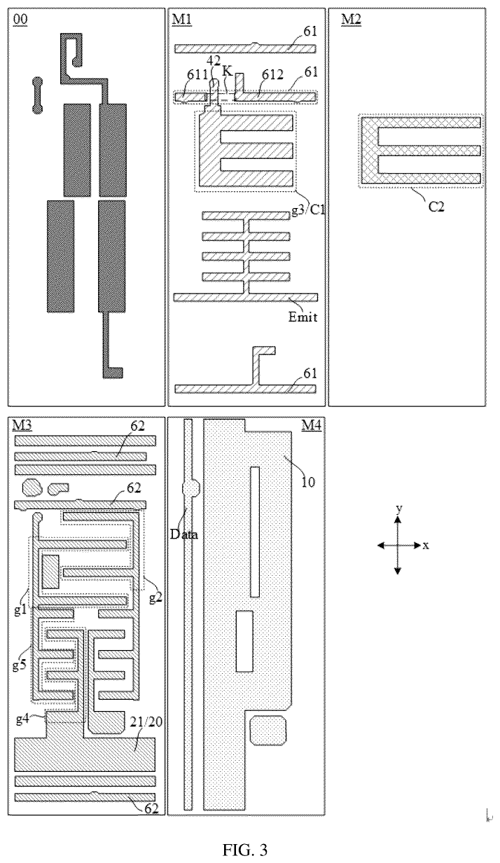

In an embodiment of the present disclosure, the display panel includes a substrate and a plurality of layers arranged at a side of the substrate. FIG. 3 is a schematic diagram of a layer decomposition of FIG. 2. FIG. 3 illustrates the patterns of the layers at the location of the pixel circuit. As shown in FIG. 3, the display panel includes a semiconductor layer 00, a first metal layer M1, a second metal layer M2, a third metal layer M3, and a fourth metal layer M4. The semiconductor layer 00, the first metal layer M1, the second metal layer M2, the third metal layer M3, and the fourth metal layer M4 are sequentially arranged away from the substrate. The first plate C1 is disposed in the first metal layer M1, the second plate C2 is disposed in the second metal layer M2, the second signal line 20 is disposed in the third metal layer M3, and the first signal line 10 is disposed in the fourth metal layer M4. That is, the first signal line 10 and the second signal line 20 are disposed at the side of the second plate C2 away from the substrate. The gates of the transistors in the pixel circuit are disposed in the first metal layer M1. The second metal layer M2, in which the second plate C2 of the storage capacitor Cst is disposed, is typically made of the same material as the first metal layer M1, such as molybdenum. Other metal layers disposed at the side of the second metal layer M2 away from the substrate may be made of the same material, such as titanium and/or aluminum. For example, the third metal layer M3 and the fourth metal layer M4 both have a titanium/aluminum/titanium three-layer metal structure. That is, an aluminum metal layer is stacked on a titanium metal layer, and a titanium metal layer is stacked on the aluminum metal layer. Adjacent metal layers in the three-layer metal structure are in direct contact with each other to form a three-layer metal stack structure. Insulation is provided between the semiconductor layer 00 and the first metal layer M1, and between adjacent metal layers (such as the first metal layer M1 and the second metal layer M2).

The first signal line 10 disposed in the fourth metal layer M4 and the second plate C2 disposed in the second metal layer M2 are made of different metal materials, resulting in a difference in square resistance between the two. The square resistance of the first signal line 10 is smaller than the square resistance of the second plate C2. When the first signal line 10 is used to transmit the power signals, even if a plurality of second plates C2 in a pixel circuit row are interconnected to form a transverse wiring, the difference in square resistance between the first signal line 10 and the transverse wiring also affects the uniformity of the power signals to a certain extent. In addition, for the display panels used in long horizontal screens, the length of the transverse wiring formed by interconnecting a plurality of second plates C2 is generally greater than the length of the first signal line 10 extending longitudinally, resulting in a greater difference in impedance between the transverse wiring and the first signal line 10, affecting the in-plane uniformity of the power signals, and thus affecting the display uniformity. In an embodiment of the present disclosure, a second signal line 20 is additionally provided. The second signal line 20 is disposed in the third metal layer M3, and the first signal line 10 is disposed in the fourth metal layer M4. The square resistance of the second signal line 20 is approximately the same as the square resistance of the first signal line 10. The second signal line 20 is electrically connected to the first signal line 10 in a crossing manner to form a mesh wiring, which improves the in-plane uniformity of the power signals. By connecting the second plate C2 of the storage capacitor Cst to the mesh wiring with better signal uniformity at the location of each pixel circuit 30, the uniformity of the power signals received at the location of each pixel circuit 30 is better, thereby improving the display uniformity. The application in display panels of the long horizontal screens can improve display uniformity.

In some embodiments, the light-emitting device in the display panel is light-emitting diode (LED), such as Micro LED or Mini LED. Micro LED devices require a relatively high current to drive, and Micro LED display panels have higher requirements for in-plane uniformity of the signals. According to the design of the embodiment of the present disclosure, the second signal line 20 is additionally provided in the third metal layer M3. The square resistance of the second signal line 20 is approximately the same as the square resistance of the first signal line 10. The second signal line 20 crosses the first signal line 10 in the transverse and longitudinal directions to form the mesh wiring, which can improve the in-plane uniformity of the power signals. By connecting the second plate C2 of the storage capacitor Cst to the mesh wiring with better signal uniformity at the location of each pixel circuit 30, the uniformity of the power signals received at the location of each pixel circuit 30 is better, thereby meeting the driving requirements of Micro LED devices and improving the display uniformity.

In some embodiments of the present disclosure, the first signal line 10 and the second signal line 20 are made of the same material. Such a configuration makes the square resistance of the second signal line 20 similar to the square resistance of the first signal line 10. The second signal line 20 is electrically connected to the first signal line 10 in a crossing manner to form the mesh wiring, which can improve the in-plane uniformity of the power signals. By connecting the second plate C2 of the storage capacitor Cst to the mesh wiring with better signal uniformity at the location of each pixel circuit 30, the uniformity of the power signals received at the location of each pixel circuit 30 is better, thereby improving the display uniformity.

In some embodiments, in conjunction with FIG. 2 and FIG. 3, the display panel includes a scan line 60 extending along the second direction x. The scan line 60 includes a first scan sub-line 61 and a second scan sub-line 62. The first scan sub-line 61 is electrically connected to the second scan sub-line 62, and the first scan sub-line 61 and the second scan sub-line 62 extend along the second direction x. FIG. 2 is a top view of the display panel, with the top view direction parallel to a direction perpendicular to the plane of the display panel. The scan lines 60 shown in FIG. 2 include a scan line connected to the gate reset transistor T1, a scan line connected to the electrode reset transistor T2, and a scan line connected to the data writing transistor T3 and the threshold compensation transistor T4.

As shown in FIG. 2, along the direction perpendicular to the plane of the display panel, the first scan sub-line 61 at least partially overlaps the second scan sub-line 62. The first scan sub-line 61 is disposed in the same layer as the gate of the drive transistor Tm, and the second scan sub-line 62 is disposed in the same layer as the second signal line 20. In conjunction with FIG. 3, the second scan sub-line 62 is disposed in the third metal layer M3, while the first scan sub-line 61 is disposed in the first metal layer M1. The square resistance of the second scan sub-line 62 is smaller than the square resistance of the first scan sub-line 61. The second scan sub-line 62 is used to transmit the scan signal, which can reduce the voltage drop on the scan line 60, improve the uniformity of the scan signal in the second direction x, and thus improve the display uniformity. Furthermore, the second scan sub-line 62 and the second signal line 20, which extend in the same direction, are disposed in the same layer, and the signal lines extending in the same direction are located in the same metal layer, which realizes the rational utilization of the metal layer and saves the wiring space of the display panel.

In an embodiment of the present disclosure, the second scan sub-line 62 extending along the second direction x is provided, and the second scan sub-line 62 is used to transmit the scan signal, which can reduce the voltage drop on the scan line 60. In the display panel, a data line Data extends along the first direction x. The pixel circuit 30 is electrically connected to the data line Data, and the data line Data provides a data signal Data to the pixel circuit 30. The extension directions of the data line Data and the second scan sub-line 62 intersect with each other, so it is necessary to dispose the data line Data and the second scan sub-line 62 in different layers. In an embodiment of the present disclosure, the data line Data is additionally disposed in the fourth metal layer M4 to meet the routing requirements of the data line Data and the second scan sub-line 62. Meanwhile, the first signal line 10 extending in the same direction as the data line Data is also disposed in the fourth metal layer M4, that is, the data line Data and the first signal line 10 are disposed in the same layer. On this basis, to reduce the voltage drop during power signal transmission, in an embodiment of the present disclosure, the second signal line 20 extending along the second direction x is provided, and the second signal line 20 and the second scan sub-line 62 are disposed in the same layer. The second signal line 20 is formed by using the existing layer of the display panel, without adding any new processes. Furthermore, the second signal line 20 is electrically connected to the existing first signal line 10 in a crossing manner to form a mesh wiring, which can reduce the voltage drop of the display panel during power signal transmission, so that the uniformity of the power signals received at the location of each pixel circuit is better, thereby improving the display uniformity.

Furthermore, a connection electrode 70 is further disposed in the fourth metal layer M4. The connection electrode 70 is connected to the second light-emitting control transistor T6 through a via hole passing through an insulating layer. The connection electrode 70 is further connected to the first electrode of the light-emitting device PD through the via hole (not shown in FIG. 2).

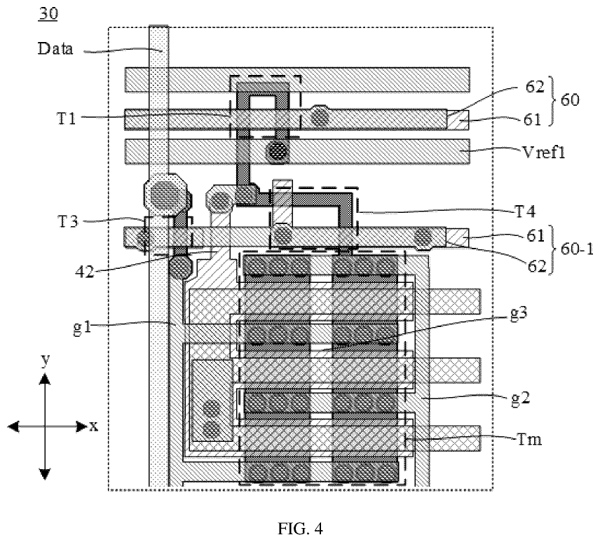

FIG. 4 is an enlarged view of a local portion in FIG. 2. FIG. 4 illustrates the upper half of the pixel circuit 30 in FIG. 2. To clearly illustrate the connections around the drive transistor Tm, the first signal line 10 that overlaps the drive transistor Tm is not shown in FIG. 4. As shown in FIG. 4, the pixel circuit 30 includes the data writing transistor T3 and the threshold compensation transistor T4. The data writing transistor T3 is connected to a first electrode g1 of the drive transistor Tm, and the threshold compensation transistor T4 is connected between a second electrode g2 and a gate g3 of the drive transistor Tm. The pattern shapes of the first electrode g1, the second electrode g2, and gate g3 of the drive transistor Tm may be seen with reference to FIG. 3.

The scan line 60 includes a first scan line 60-1. A gate of the data writing transistor T3 and a gate of the threshold compensation transistor T4 are electrically connected to the first scan line 60-1. The first scan line 60-1 includes a first scan sub-line 61 and a second scan sub-line 62. The first scan sub-line 61 of the first scan line 60-1 includes a first segment 611 and a second segment 612. A break K is located between the first segment 611 and the second segment 612 (see FIG. 3). The gate of the data writing transistor T3 is electrically connected to the first segment 611, and the gate of the threshold compensation transistor T4 is electrically connected to the second segment 612. The display panel includes a second extension portion 42. An end of the second extension portion 42 is connected to the gate of the drive transistor Tm, and another end is connected to the threshold compensation transistor T4. The second extension portion 42 is disposed in the same layer as the gate g3 of the drive transistor Tm and passes through the break K. In an embodiment of the present disclosure, the second extension portion 42 is disposed in the same layer as the first scan sub-line 61 and the gate g3 of the driver transistor Tm. Since the first scan sub-line 61 can ensure the transmission of the scan signal, the first scan sub-line 61 can be disconnected at a local position to form the break K. The second extension portion 42 connected to the gate g3 of the drive transistor Tm and disposed in the same layer is connected to the threshold compensation transistor T4 after being passed through by the break K, which can reduce the number of via holes at the location of the drive transistor Tm.

In some embodiments of the present disclosure, the second signal line 20 extending along the second direction x is additionally provided in the display panel, and the second signal line 20 may be disposed at a plurality of positions. In some embodiments, the second signal line 20 is disposed at a side of the first light-emitting control transistor T5 away from the drive transistor Tm along the first direction y. In some embodiments, the second signal line 20 is disposed between the first light-emitting control transistor T5 and the drive transistor Tm. The following embodiments illustrate, by way of example, the arrangement of the second signal line 20 in the display panel and how the second signal line 20 is electrically connected to the first signal line 10.

In some embodiments, as shown in FIG. 2, the pixel circuit 30 includes the first light-emitting control transistor T5. A first electrode g4 of the first light-emitting control transistor T5 is electrically connected to the first signal line 10, and a second electrode g5 of the first light-emitting control transistor T5 is connected to the drive transistor Tm. FIG. 3 illustrates the positions of the first electrode g4 and the second electrode g5 of the first light-emitting control transistor T5. The second signal line 20 includes a first signal sub-line 21, which is disposed at a side of the first light-emitting control transistor T5 away from the drive transistor Tm along the first direction y. In an embodiment of the present disclosure, the first electrode g4 of the first light-emitting control transistor T5 is electrically connected to the first signal line 10. The first signal sub-line 21 is disposed adjacent to the first light-emitting control transistor T5, which facilitates the first signal sub-line 21 being electrical connected to the first signal line 10 through the first electrode g4 of the first light-emitting control transistor T5.

In some embodiments of the present disclosure, the first signal sub-line 21 and the first electrode g4 of the first light-emitting control transistor T5 are disposed in the same layer and electrically connected to each other. As shown in FIG. 3, the first signal sub-line 21 and the first electrode g4 of the first light-emitting control transistor T5 are disposed in the third metal layer M3, and the first signal sub-line 21 is integrated with the first electrode g4 of the first light-emitting control transistor T5. In the existing routing structure of the pixel circuit, the first electrode g4 of the first light-emitting control transistor T5 requires a via hole to connect to the first signal line 10. In an embodiment of the present disclosure, the first sub-signal line 21 and the first electrode g4 of the first light-emitting control transistor T5 are disposed in the same layer and electrically connected to each other, so that the first sub-signal line 21 is connected to the first signal line 10 through the first electrode g4, an insulating layer is not required to punch the via hole in the display panel.

FIG. 2 is a top view of the display panel. It should be understood that the top view direction is parallel to the direction perpendicular to the plane of the display panel. As shown in FIG. 2, along the direction perpendicular to the plane of the display panel, the first electrode g4 of the first light-emitting control transistor T5 at least partially overlaps the first signal line 10. The first electrode g4 of the first light-emitting control transistor T5 is electrically connected to the first signal line 10 through a first via hole VI passing through the insulating layer. FIG. 2 illustrates two first via holes V1 arranged side by side, which can reduce the impedance of the via hole connection and improve electrical connection performance.

As shown in FIG. 2, the pixel circuit 30 includes an electrode reset transistor T2, and the electrode reset transistor T2 is electrically connected to an electrode of the light-emitting device (not shown in FIG. 2). Along the direction perpendicular to the plane of the display panel, the first signal sub-line 21 overlaps a gate g6 of electrode reset transistor T2. Such a configuration makes the layout of the pixel circuit 30 more compact, thereby saving wiring space of the display panel.

In addition, as shown in FIG. 2, the display panel includes a first reset signal line Vref1 and a second reset signal line Vref2 extending along the second direction x. The first reset signal line Vrefl provides a first reset signal Vref1, and the second reset signal line Vref2 provides a second reset signal Vref2. The gate reset transistor T1 is electrically connected to the first reset signal line Vref1, and the electrode reset transistor T2 is electrically connected to the second reset signal line Vref2. The second reset signal line Vref2 is disposed at a side of the first signal sub-line 21 away from the first light-emitting control transistor T5, and the second reset signal line Vref2 and the first signal sub-line 21 are disposed in the same layer. Such a configuration facilitates the first signal sub-line 21 to be connected to the first signal line 10 through the first electrode g4 of the first light-emitting control transistor T5, an insulating layer is not required to punch the via hole in the display panel.

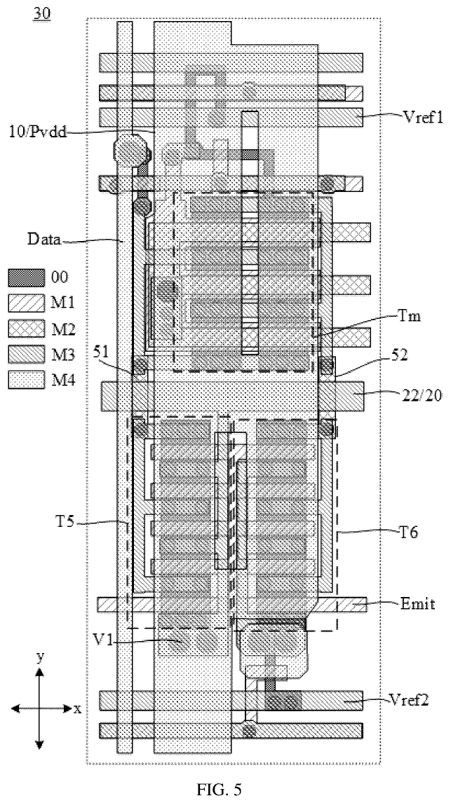

FIG. 5 is a partial schematic diagram of a further display panel according to an embodiment of the present disclosure. The connection between the transistors in the pixel circuit of FIG. 5 can be understood in conjunction with FIG. 1. As shown in FIG. 5, the pixel circuit 30 includes the first light-emitting control transistor T5. The first electrode of the first light-emitting control transistor T5 is electrically connected to the first signal line 10, and the second electrode of the first light-emitting control transistor T5 is connected to the first electrode of the drive transistor Tm. The second signal line 20 includes a second signal sub-line 22, and the second signal sub-line 22 is disposed between the drive transistor Tm and the first light-emitting control transistor T5. In an embodiment of the present disclosure, the first electrode g4 of the first light-emitting control transistor T5 is electrically connected to the first signal line 10. The first signal sub-line 21 is disposed adjacent to the first light-emitting control transistor T5, which facilitates the first signal sub-line 21 being electrical connected to the first signal line 10 through the first electrode g4 of the first light-emitting control transistor T5.

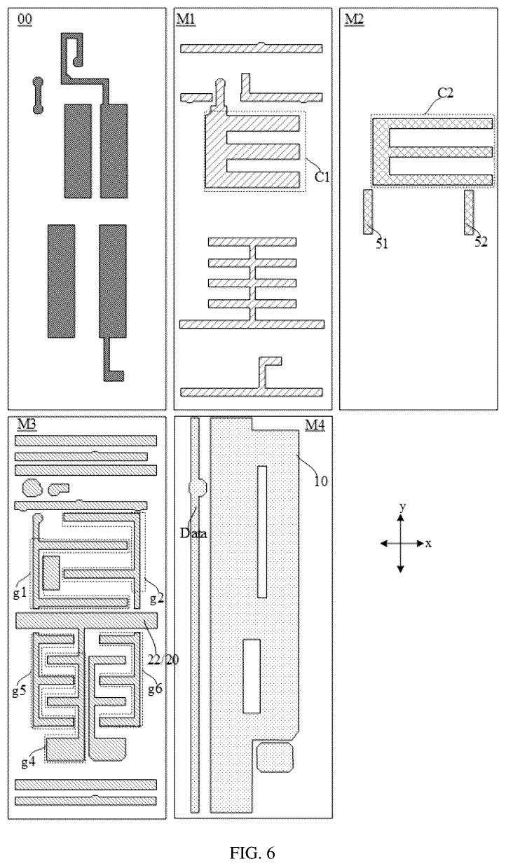

FIG. 6 is a schematic diagram of a layer decomposition of FIG. 5. FIG. 6 illustrates the patterns of the layers at the location of the pixel circuit. As shown in FIG. 6, the display panel includes the semiconductor layer 00, the first metal layer M1, the second metal layer M2, the third metal layer M3, and the fourth metal layer M4. The semiconductor layer 00, the first metal layer M1, the second metal layer M2, the third metal layer M3, and the fourth metal layer M4 are sequentially arranged away from the substrate. The first plate C1 is disposed in the first metal layer M1, the second plate C2 is disposed in the second metal layer M2, the second signal sub-line 22 included in the second signal line 20 is disposed in the third metal layer M3, and the first signal line 10 is disposed in the fourth metal layer M4.

As shown in FIG. 5, the second signal sub-line 22 and the first electrode g4 of the first light-emitting control transistor T5 are disposed in the same layer and electrically connected to each other. As shown in FIG. 6, the second signal sub-line 22 and the first electrode g4 of the first light-emitting control transistor T5 are disposed in the third metal layer M3, and the second signal sub-line 22 is integrated with the first electrode g4 of the first light-emitting control transistor T5. In the existing routing structure of the pixel circuit, the first electrode g4 of the first light-emitting control transistor T5 requires a via hole to connect to the first signal line 10. In an embodiment of the present disclosure, the second sub-signal line 22 and the first electrode g4 of the first light-emitting control transistor T5 are disposed in the same layer and electrically connected to each other, so that the second sub-signal line 22 is connected to the first signal line 10 through the first electrode g4, and an insulating layer via hole is not required in the display panel.

As shown in the top view of FIG. 5, along the direction perpendicular to the plane of the display panel, the first electrode g4 of the first light-emitting control transistor T5 at least partially overlaps the first signal line 10. The first electrode g4 of the first light-emitting control transistor T5 is electrically connected to the first signal line 10 through the first via hole VI passing through the insulating layer. In this embodiment, the first signal sub-line 21 is connected to the first signal line 10 through the first electrode g4, an insulating layer is not required to punch the via hole in the display panel.

In conjunction with FIG. 5 and FIG. 6, the second electrode g5 of the first light-emitting control transistor T5 is connected to the first electrode g1 of the drive transistor Tm, and the first electrode g6 of the second light-emitting control transistor T6 is connected to the second electrode g2 of the drive transistor Tm. The second light-emitting control transistor T6 is disposed at a side of the second signal sub-line 22 away from the drive transistor Tm. A first bridging line 51 is connected between the second electrode g5 of the first light-emitting control transistor T5 and the first electrode g1 of the drive transistor Tm, and a second bridging line 52 is connected between the first electrode g6 of the second light-emitting control transistor T6 and the second electrode g2 of the drive transistor Tm. Along the direction perpendicular to the plane of the display panel, the second signal sub-line 22 crosses the first bridging line 51 in an insulated manner, and the second signal sub-line 22 crosses the second bridging line 52 in an insulated manner. In an embodiment of the present disclosure, the second signal sub-line 22 is disposed between the drive transistor Tm and the first light-emitting control transistor T5. Since the second signal sub-line 22, the second electrode g5 and the first electrode g4 of the first light-emitting control transistor T5, and the first electrode g1 and the second electrode g2 of the drive transistor Tm are disposed in the same layer, the first bridging line 51 and the second bridging line 52 are provided to prevent the second signal sub-line 22 from being short-circuited with other circuits disposed in the same layer, thereby ensuring the normal connection between the first light-emitting control transistor T5 and the first electrode g1 of the drive transistor Tm, and the normal connection between the second light-emitting control transistor T6 and the second electrode g2 of the drive transistor Tm.

In some embodiments, as shown in FIG. 5 and FIG. 6, the first bridging line 51 and the second bridging line 52 are disposed in the same layer as the second plate C2, both disposed in the second metal layer M2. The first bridging line 51 and the second bridging line 52 are manufactured in the same process as the second plate C2, which simplifies the manufacturing process of the display panel.

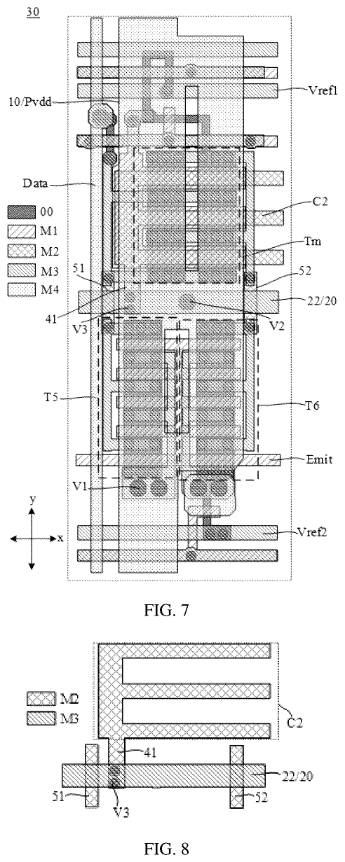

FIG. 7 is a partial schematic diagram of a further display panel according to an embodiment of the present disclosure. As shown in FIG. 7, the second signal line 20 includes the second signal sub-line 22, and the second signal sub-line 22 is disposed between the drive transistor Tm and the first light-emitting control transistor T5. Along the direction perpendicular to the plane of the display panel, the second signal sub-line 22 at least partially overlaps the first signal line 10. The second signal sub-line 22 is electrically connected to the first signal line 10 through a second via hole V2 passing through the insulating layer. In this embodiment, the second via hole V2 is provided at the overlapping location of the second signal sub-line 22 and the first signal line 10 to realize electrical connection between the two.

In the embodiment of FIG. 5, on the basis that the second signal sub-line 22 and the first electrode g4 of the first light-emitting control transistor T5 are disposed in the same layer and electrically connected to each other, the second via hole V2 may be further provided at the overlapping location of the second signal sub-line 22 and the first signal line 10, which is not illustrated in the drawings herein.

FIG. 8 is a partial schematic diagram of a further display panel according to an embodiment of the present disclosure. FIG. 8 is only for illustrating the electrical connection between the second plate C2 of the storage capacitor and the second signal sub-line 22.

In conjunction with FIG. 7 and FIG. 8, the second signal sub-line 22 is connected to the first signal line 10 through the second via hole V2. The display panel includes a first extension portion 41, the first extension portion 41 and the second plate C2 are disposed in the same layer and electrically connected to each other. The first extension portion 41 and the second plate C2 are disposed in the second metal layer M2. Along the direction perpendicular to the plane of the display panel, the first extension portion 41 at least partially overlaps the second signal sub-line 22. The first extension portion 41 is electrically connected to the second signal sub-line 22 through a third via hole V3 passing through the insulating layer. In this embodiment, the first extension portion 41 is integrated with the second plate C2. By changing the pattern shape of the layer in which the second electrode C2 is disposed, the first extension portion 41 extends to a position overlapping the second signal sub-line 22, and the two are electrically connected through a via hole, so that the second plate C2 is electrically connected to the first signal line 10 through the second signal sub-line 22.

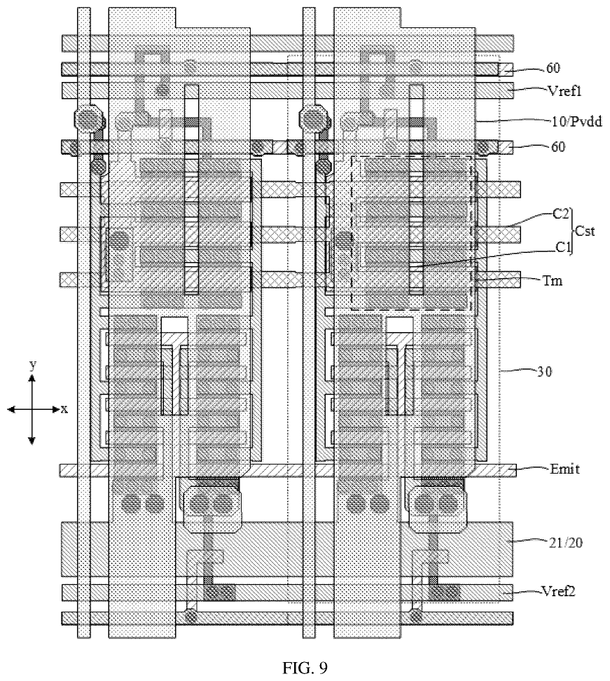

FIG. 9 is a partial schematic diagram of a further display panel according to an embodiment of the present disclosure. FIG. 9 illustrates two adjacent pixel circuits 30 in the second direction x. The arrangement of the second signal line 20 in FIG. 9 is based solely on the embodiment of FIG. 2. As shown in FIG. 9, the two second plates C2 of two adjacent pixel circuits 30 in the second direction x are electrically connected to each other. In an embodiment of the present disclosure, a plurality of second plates C2 arranged in the second direction x are electrically connected to each other to form an auxiliary power line. The display panel includes the auxiliary power line extending along the second direction x, the second signal line 20 extending along the second direction x, and the first signal line 10 extending along the first direction y. The second signal line 20 is electrically connected to the first signal line 10, and the auxiliary power line is also electrically connected to the first signal line 10, so that the power signals transmitted in the display panel is more uniform and the display uniformity is better.

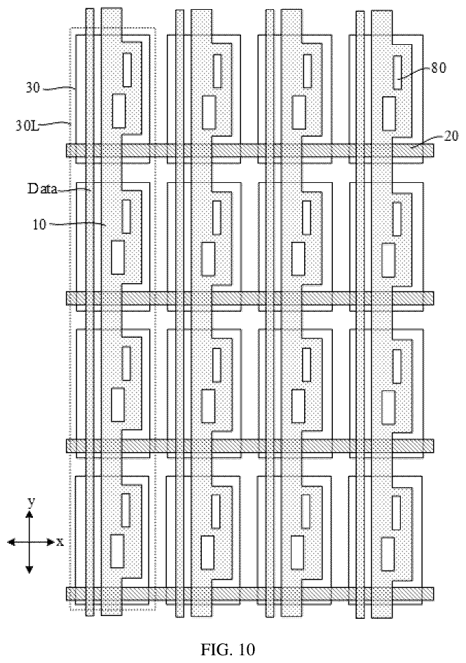

FIG. 10 is a schematic diagram of a further display panel according to an embodiment of the present disclosure. FIG. 10 only shows a simplified schematic diagram of the pixel circuit 30. As shown in FIG. 10, the plurality of pixel circuits 30 are arranged in the first direction y to form pixel circuit column 30L. Along the direction perpendicular to the plane of the display panel, the first signal lines 10 overlap the pixel circuit columns 30L. That is, one first signal line 10 is correspondingly provided for each pixel circuit column 30L. The arrangement density of the first signal lines 10 is relatively high, so that the uniformity of the power signals in the display panel is better, and the display uniformity is better.

In addition, in some embodiments, as shown in FIG. 10, the first signal line 10 has a hollow portion 80. The first signal line 10 is disposed in the fourth metal layer M4. When the fourth metal layer M4 and the third metal layer M3 are titanium/aluminum/titanium stack structures, the fourth metal layer M4 and the third metal layer M3 have relatively large layer thicknesses. An organic insulating layer is disposed between the fourth metal layer M4 and the third metal layer M3 to ensure complete coverage of the structure in the third metal layer M3. During some manufacturing processes, the organic insulating layer may generate gas. The hollow portion 80 in the first signal line 10 facilitates the discharge of gas, preventing the first signal line 10 from bulging and becoming uneven due to the inability to discharge gas.

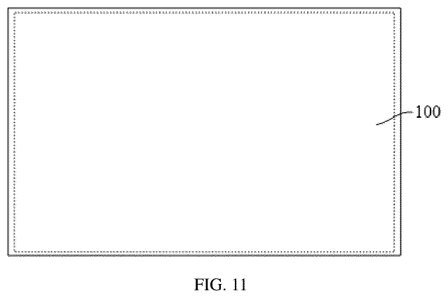

Based on the same inventive concept, an embodiment of the present disclosure provides a display apparatus. FIG. 11 is a schematic diagram of a display apparatus according to an embodiment of the present disclosure. As shown in FIG. 11, the display apparatus includes a display panel 100 according to any one of the embodiments of the present disclosure. The structure of the display panel has been described in the above embodiments and will not be repeated here. The display apparatus according to an embodiment of the present disclosure may be, for example, an electronic device with a display function, such as a mobile phone, tablet, computer, television, or smart wearable product.

In some embodiments, the light-emitting device in the display panel 100 is an LED, such as a Micro LED or a Mini LED.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, comprising:
a pixel circuit,
a first signal line extending along a first direction, and
a second signal line extending along a second direction,
wherein the first direction intersects with the second direction, and the first direction and the second direction are parallel to a plane of the display panel;
the pixel circuit comprises a drive transistor and a storage capacitor, the storage capacitor comprises a first plate and a second plate, the first plate is connected to a gate of the drive transistor, the second plate is electrically connected to the first signal line, and the second signal line is electrically connected to the first signal line; and
the second plate, the first signal line, and the second signal line are disposed in different layers from one another.

2. The display panel according to claim 1, further comprising:
a substrate, a first metal layer, a second metal layer, a third metal layer, and a fourth metal layer,
wherein the first metal layer, the second metal layer, the third metal layer, and the fourth metal layer are sequentially arranged away from the substrate;
wherein the first plate is disposed in the first metal layer, the second plate is disposed in the second metal layer, the second signal line is disposed in the third metal layer, and the first signal line is disposed in the fourth metal layer.

3. The display panel according to claim 1, wherein
the first signal line comprises a same material as the second signal line.

4. The display panel according to claim 1, wherein
a square resistance of the first signal line is smaller than a square resistance of the second plate.

5. The display panel according to claim 1, wherein
the pixel circuit comprises a first light-emitting control transistor, a first electrode of the first light-emitting control transistor is electrically connected to the first signal line, and a second electrode of the first light-emitting control transistor is connected to the drive transistor; and
the second signal line comprises a first signal sub-line, the first signal sub-line is disposed at a side of the first light-emitting control transistor along the first direction away from the drive transistor.

6. The display panel according to claim 5, wherein
the first signal sub-line is disposed in a same layer as the first electrode of the first light-emitting control transistor and is electrically connected to the first electrode of the first light-emitting control transistor.

7. The display panel according to claim 5, wherein
the pixel circuit comprises a electrode reset transistor, the electrode reset transistor is electrically connected to an electrode of a light-emitting device; and
along a direction perpendicular to the plane of the display panel, the first signal sub-line overlaps a gate of the electrode reset transistor.

8. The display panel according to claim 1, wherein
the pixel circuit comprises a first light-emitting control transistor, a first electrode of the first light-emitting control transistor is electrically connected to the first signal line, and a second electrode of the first light-emitting control transistor is connected to a first electrode of the drive transistor; and
the second signal line comprises a second signal sub-line, the second signal sub-line is disposed between the drive transistor and the first light-emitting control transistor.

9. The display panel according to claim 8, wherein
the second signal sub-line is disposed in a same layer as the first electrode of the first light-emitting control transistor and is electrically connected to the first electrode of the first light-emitting control transistor.

10. The display panel according to claim 8, wherein
along a direction perpendicular to the plane of the display panel, the first electrode of the first light-emitting control transistor at least partially overlaps the first signal line, and the first electrode of the first light-emitting control transistor is electrically connected to the first signal line through a first via hole passing through an insulating layer.

11. The display panel according to claim 8, wherein
along a direction perpendicular to the plane of the display panel, the second signal sub-line at least partially overlaps the first signal line, and the second signal sub-line is electrically connected to the first signal line through a second via hole passing through an insulating layer.

12. The display panel according to claim 11, further comprising:
a first extension portion disposed on a same layer as the second plate and electrically connected to the second plate;
wherein along the direction perpendicular to the plane of the display panel, the first extension portion at least partially overlaps the second signal sub-line, and the first extension portion is electrically connected to the second signal sub-line through a third via hole passing through the insulating layer.

13. The display panel according to claim 8, wherein
the pixel circuit comprises a second light-emitting control transistor, a first electrode of the second light-emitting control transistor is connected to a second electrode of the drive transistor, and the second light-emitting control transistor is disposed at a side of the second signal sub-line away from the drive transistor;
a first bridging line is connected between the second electrode of the first light-emitting control transistor and the first electrode of the drive transistor, and a second bridging line is connected between the first electrode of the second light-emitting control transistor and the second electrode of the drive transistor; and
along a direction perpendicular to the plane of the display panel, the second signal sub-line crosses the first bridging line in an insulated manner, and the second signal sub-line crosses the second bridging line in an insulated manner.

14. The display panel according to claim 13, wherein
the first bridging line and the second bridging line are disposed in a same layer as the second plate.

15. The display panel according to claim 1, wherein
two second plates of two adjacent pixel circuits in the second direction are electrically connected to each other.

16. The display panel according to claim 1, wherein
a plurality of pixel circuits are arranged in the first direction to form a pixel circuit column; and
along a direction perpendicular to the plane of the display panel, the first signal line at least partially overlaps the pixel circuit column.

17. The display panel according to claim 1, further comprising:
a scan line extending along the second direction,
wherein the scan line comprises a first scan sub-line and a second scan sub-line, the first scan sub-line is electrically connected to the second scan sub-line, and along a direction perpendicular to the plane of the display panel, the first scan sub-line at least partially overlaps the second scan sub-line; and
the first scan sub-line is disposed in a same layer as the gate of the drive transistor, and the second scan sub-line is disposed in a same layer as the second signal line.

18. The display panel according to claim 17, further comprising:
a data line electrically connected to the pixel circuit;
wherein the data line is disposed in a same layer as the first signal line.

19. The display panel according to claim 17, wherein
the pixel circuit comprises a data writing transistor and a threshold compensation transistor, the data writing transistor is connected to a first electrode of the drive transistor, and the threshold compensation transistor is connected between a second electrode of the drive transistor and the gate of the drive transistor;
the scan line comprises a first scan line, a gate of the data writing transistor and a gate of the threshold compensation transistor each are electrically connected to the first scan line;
a first scan sub-line of the first scan line comprises a first segment and a second segment, a break is located between the first segment and the second segment, the gate of the data writing transistor is electrically connected to the first segment, and the gate of the threshold compensation transistor is electrically connected to the second segment; and
the display panel further comprises a second extension portion, one end of the second extension portion is connected to the gate of the drive transistor and another one end of the second extension portion is connected to the threshold compensation transistor, the second extension portion is disposed in a same layer as the gate of the drive transistor, and the second extension portion passes through the break.

20. A display apparatus, comprising a display panel, wherein the display panel comprises:
a pixel circuit,
a first signal line extending along a first direction, and
a second signal line extending along a second direction,
wherein the first direction intersects with the second direction, and the first direction and the second direction are parallel to a plane of the display panel;
the pixel circuit comprises a drive transistor and a storage capacitor, the storage capacitor comprises a first plate and a second plate, the first plate is connected to a gate of the drive transistor, the second plate is electrically connected to the first signal line, and the second signal line is electrically connected to the first signal line; and
the second plate, the first signal line, and the second signal line are disposed in different layers from one another.
